(19) United States
(12) Patent Application Publication
(10) Pub. No.: US 2016/0254173 A1
(43) Pub. Date: Sep. 1, 2016

(54) SPATIALLY LIMITED PROCESSING OF A SUBSTRATE

(71) Applicants: Gregory KNIGHT, Winchester, MA (US); Michael BERGMAN, Somerville, MA (US)

(72) Inventors: Oscar EDGERLY, (US); Gregory KNIGHT, Winchester, MA (US); Michael BERGMAN, Somerville, MA (US)

(21) Appl. No.: 15/011,333

(22) Filed: Jan. 29, 2016

Related U.S. Application Data
(63) Continuation of application No. PCT/US2014/048430, filed on Jul. 28, 2014.
(60) Provisional application No. 61/859,357, filed on Jul. 29, 2013.
(60) Provisional application No. 61/865,121, filed on Aug. 12, 2013.

(51) Int. Cl. H01L 21/677; H01L 21/67

(52) U.S. Cl. CPC H01L 21/67706; H01L 21/67075; H01L 21/6776; H01L 21/6704

(57) ABSTRACT

A method of chemical processing includes passing a substrate material from a first transfer conveyor device to a second transfer conveyor device across a fluid reservoir so that a first surface of the substrate contacts a fluid within the reservoir and a second surface of the substrate is substantially untouched by the fluid within the reservoir and the first and second transfer conveyor devices are placed substantially outside of the reservoir.

### CROSS-REFERENCE TO RELATED APPLICATIONS

The present application is a continuation of PCT patent application number PCT/US2014/048430 having an international filing date of 28 Jul. 2014 and entitled SPATIALLY LIMITED PROCESSING OF A SUBSTRATE, which claims the benefit of U.S. provisional patent application No. 61/859,357 filed Jul. 29, 2013 and of U.S. provisional patent application No. 61/865,121 filed Aug. 12, 2013, the disclosures of all of which are herewith incorporated in the present application by reference.

### FIELD OF THE INVENTION

The present invention relates to the chemical processing of a substrate material, and more particularly to the selective chemical processing of a substrate material.

### SUMMARY

In the chemical processing of a substrate it may be advantageous to achieve a chemical reaction on one or more sides of the substrate while minimizing or substantially avoiding a similar activity on one or more further sides of the substrate. While various attempts to produce such an effect have been made in the past, and notwithstanding prolonged, and significant investment of time and effort supporting such attempts, they have failed, for various reasons, to achieve all of the desirable effects now exhibited by the present invention. These and other advantages and features of the invention will be more readily understood in relation to the following detailed description of the invention, which is provided in conjunction with the accompanying drawings.

It should be noted that, while the various figures show respective aspects of the invention, no one figure is intended to show the entire invention. Rather, the figures together illustrate the invention in its various aspects and principles. As such, it should not be presumed that any particular figure is exclusively related to a discrete aspect or species of the invention. To the contrary, one of skill in the art would appreciate that the figures taken together reflect various embodiments exemplifying the invention.

### BRIEF DESCRIPTION OF THE DRAWINGS

FIG. 1 shows, in block diagram form, a photovoltaic cell manufacturing process corresponding to certain aspects of the invention;

FIG. 2 shows, in block diagram form, a further photovoltaic cell manufacturing process corresponding to certain aspects of the invention;

FIG. 3 shows, in schematic form, an elevated cross-sectional view of one embodiment of the invention;

FIG. 4 shows, in photographic form, exemplary components of one embodiment of the invention; and

FIGS. 5A-5D show, in photographic form, the progress of a substrate material through processing according to one embodiment of the invention.

FIG. 6A shows, in schematic cross-section, certain aspects of a reservoir portion of a device according to principles of the invention;

FIG. 6B shows, in schematic perspective view, certain aspects of a reservoir portion of a device according to principles of the invention;

FIG. 7 shows, in schematic perspective view, certain aspects of a further reservoir portion of a device according to principles of the invention;

FIG. 8 shows, in schematic perspective view, certain aspects of another reservoir portion of a device according to principles of the invention;

FIG. 9 shows, in schematic perspective view, certain aspects of still another reservoir portion of a device according to principles of the invention;

FIG. 10 shows, in schematic perspective view, certain aspects of yet still another reservoir portion of a device according to principles of the invention;

FIG. 11 shows, in schematic cross-section, certain aspects of a further reservoir portion of a device according to principles of the invention;

FIG. 12 shows, in schematic cross-section, certain aspects of a further portion of a device according to principles of the invention; and

FIG. 13 shows, in schematic cross-section, certain aspects of an integrated reservoir portion of a device according to principles of the invention.

### DETAILED DESCRIPTION

The processing of a single side of a substrate, and more particularly, avoiding the processing of a further side of the substrate, can be advantageous in many chemical processing schemes. For example, in the preparation of printed circuit boards, it may be desirable to remove a substance, by etching or dissolution, from one side of a printed circuit substrate while leaving a similar material present on a further side of the substrate. In like fashion, selective addition of a material may be advantageous. In exemplary applications, the substrate may include a fiberglass reinforced polyester, a biaxially oriented polyester terephthalate (BoPET—mylar®) material, a ceramic material, or any other appropriate material. Similarly, in the manufacture of integrated circuits and photovoltaic devices, there are times when a processing specification demands that a particular chemistry be applied to one side of a substrate such as a silicon wafer, for example, and not to another side thereof.

The present invention includes a system, method and apparatus arranged to support a substrate material with a conveying device and transferring that substrate material across a substantially fluid (e.g. liquid) phase processing material so that at least one side of the substrate material is substantially uncontacted by the liquid phase processing material (it will be understood that a fluidized bed material may be employed). In one exemplary arrangement, the liquid phase material is contained in a reservoir having a first edge and a second edge so that the liquid phase material is substantially retained between the edges. A first transfer conveyor device is disposed adjacent to the first edge and a second transfer conveyor device is disposed adjacent to the second edge. A substrate material is arranged to be supported by the first transfer conveyor which, in operation passes the subject material from the first transfer conveyor to the second transfer conveyor. The second transfer conveyor is arranged to receive the substrate material from the first transfer conveyor and assume support of the substrate material as the first transfer conveyor is relieved of that role.

The reservoir, being disposed between the two transfer conveyors, is arranged to maintain an upper surface of the substantially fluid phase processing material in a spatial position such that a lower surface of the substrate material, and in sonic cases edge surfaces of the substrate material, come into contact with the substantially liquid phase material as the substrate material transitions from being supported by the first transfer conveyor device to the second transfer conveyor device. During this contact, a desirable physical and/or chemical process may take place at the interface between the substrate material and the substantially fluid phase material. Depending on the physical characteristics of the substrate material and the liquid phase material, some of the liquid phase material may adhere to the substrate material as the substrate passes on to the second conveyor device. In other cases, a negligible amount of the liquid phase material may adhere to the substrate material as the substrate passes on to the second conveyor device. In still further embodiments, the second conveyor device may include or be placed adjacent to a further device adapted to actively remove the liquid phase material from the substrate material during its transition from the reservoir to the second conveyor device.

The arrangement described above, and variations to be illustrated herewith, exhibits significant advantages over alternative arrangements including purely atomized fluid devices and devices where one or more transfer conveyor devices are submerged within the processing fluid. Where a transfer conveyor device is submerged within the processing fluid, for example, erosion of components of the transfer device, either by chemical action or by physical friction, can result in undesirable contamination of the processing fluid.

It should be understood that a wide variety of arrangements of the reservoir can be applied in various embodiments prepared according to principles of the invention. For example, fluid level may be maintained by active control of direct pumped fluid, by active control of a fluid level in a remote reservoir or by a weir-overflow arrangement, and by various other passive control arrangements. In addition, various manual and/or automatic control approaches may be applied to maintain a particular chemical and/or physical characteristic of the processing fluid. In addition, the reservoir may include a substantially open top, a perforated closed top, a slotted top, and various other configurations that would all be readily understood by one of skill in the art in light of the present disclosure.

Selected figures illustrating the disclosed invention are attached hereto.

One exemplary industrial process in which the present invention, in its various embodiments, will be applied to good effect is the production of photovoltaic solar cells. Typically, the production of photovoltaic cells involve the processing of a semiconductor substrate to produce a lateral doped junction within the cell and generally parallel to an upper surface of the cell. Thus, in an exemplary cell, a generally planar wafer is provided as a substrate. The wafer is processed to produce the doped junction, and to produce an upper surface having antireflective characteristics. This results in an optimize acquisition of photons incident on the upper surface.

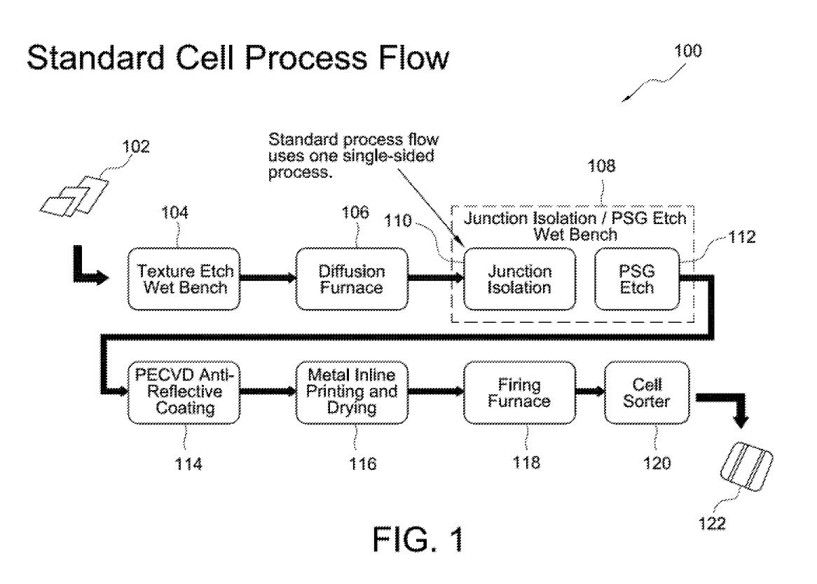

FIG. 1 shows, as rendered by the inventor, a first exemplary process 100 for the manufacture of such photovoltaic cells. In the illustrated process 100, prepared substrate wafers 102 are introduced into a first step of the process which is a texture etch 104. Typically the prepared substrate wafer will include a bulk doping (positive or negative) according to the requirements of the particular process. The texture etch provides a roughening of the external surfaces of the substrate to provide improved photon capture.

After completion of the texture etch process 104, the wafer is introduced into a diffusion furnace 106 where an alternate doping is introduced into the surface regions of the substrate wafer by thermal diffusion. Typically, this involves the introduction of a gaseous-state reactant into the thermal diffusion furnace and contemporaneous heating of the substrate wafer and gaseous state reactant. Because of the high temperatures within the diffusion furnace, sonic of the gaseous reactant tends to diffuse into exposed surfaces of the wafer, thus changing the conductivity characteristics of those regions.

Typically, it is desirable to effect this change in conductivity adjacent to what will be the upper surface of the photovoltaic cell. However, because the doping reactant diffuses into all exposed surface regions, undesirably doped regions having elevated conductivity will typically exist within the substrate after diffusion furnace processing. These undesirably doped regions, if not removed, will result in short-circuiting of the cell and diminution or destruction of the cell's photoconversion effectiveness. Consequently, further processes are provided to eliminate these undesirably doped regions.

The elimination of undesirably doped regions takes place in a junction isolation and phosphosilicate glass etch shown as step 108 in the process 100. Junction isolation 110 generally involves the removal of undesirably doped and conductive regions around the edges of the substrate wafer. Phosphosilicate glass (PSG) etch 112 removes a layer of phosphosilicate glass that tends to form on surfaces of the substrate wafer during processing in the diffusion furnace 106. Both of these processes typically are performed as liquid phase processes employing aggressive acidic etchants such as, for example, hydrofluoric acid.

Historically, junction isolation and PSG etch were effected as bulk immersion processes in which the entire wafer was placed within a fluid bath. Such processing required the masking of regions of the substrate where etching was not desired prior to immersion, and the subsequent removal of any masking device. Such masking and mask removal represent significant additional processing inputs that tend to elevate the cost of the finished photovoltaic cell and increase overall process risk.

More recently a variety of efforts have been made to localize processing to a single side or region of the cell, as described above. Prior to the present invention, however, such efforts have met with limited success. Now, however, surprising and significant improvements are available by the application of the inventions described herewith.

After junction isolation and PSG etch 108, the work in process substrate is generally exposed to a PECVD antireflective coating process 114 where an antireflective coating is applied to at least an upper surface of the cell so as to further optimize the absorption of incident photons. This is followed by the application of metal contacts at a metal in-line printing and drying process step 116 and the subsequent firing of the work in process cell 118 to fuse the metal to the surface of the substrate and form an effective ohmic contact.

Subsequent to firing, work in process cells are typically tested and sorted 120 characterizing the resulting output cells 122. Properly characterized, these cells can then be assigned alone or in combination to various applications.

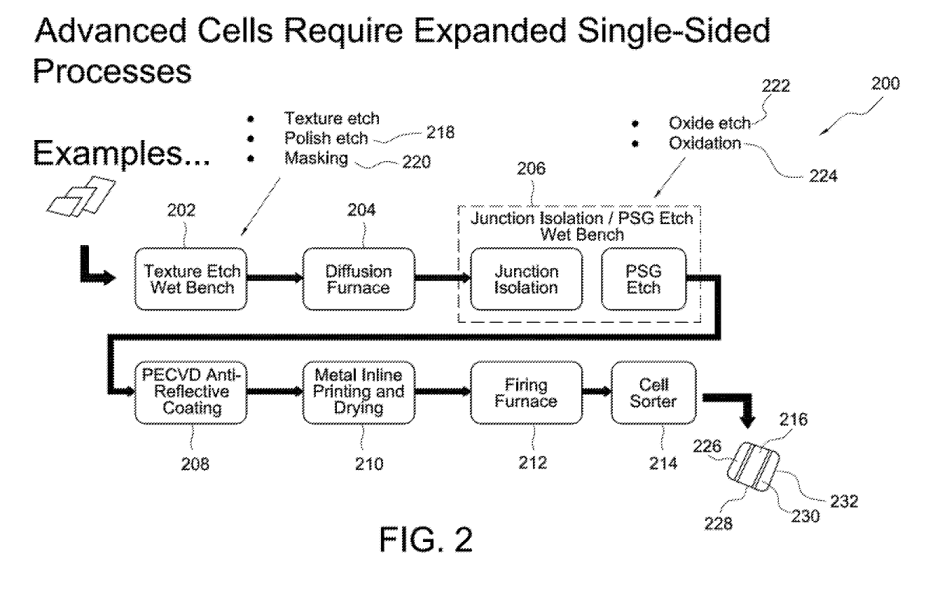

FIG. 2 shows, in block diagram form, a further processing regimen 200 associated with the manufacturing of more advanced photovoltaic cells. Like process 100, advanced process 200 typically will include a texture etch step 202, a diffusion step 204, a junction isolation and PSG etch step 206, a PECVD antireflective coating step 208, a metal in-line printing and drying step 210, a firing step 212, and a cell testing and sorting step for cell characterization 214 so as to produce characterized finished cells 216. It will be noted, however, that the more advanced process 200 may also include a polish etch 218 and masking 220 processes, where the texture etch, 202, polish etch 218 and masking 220 steps may benefit from the availability of a single-sided processing mechanism. Likewise, the advanced process 200 may include a further oxide etch 222 and an oxidation step 224 associated with the junction isolation and PSG etch wet processing 206. These further steps 222 and 224 also will, in certain circumstances, benefit from the availability of an effective single-sided processing mechanism.

Other advanced cell processes that may require and/or benefit from a single-sided processing mechanism include interdigitated back contact formation 226 (IBC), the production of passivated emitter and rear cells (PERC) 228, the production of passivated emitter and rear locally diffused cells 230 (PERL), and the production of bifacial cells 232 and of other cell constructions. All of these processes, while suggesting the possibility of significant improvements, have been hampered in their execution by the lack of a reliable and effective single-sided processing mechanism such as that now disclosed. Moreover, the additional process steps associated with each of these advanced processes imply a corresponding requirement for additional processing equipment. Such additional processing equipment, in turn, requires substantial additional capital investment (both in the equipment itself and in the floorspace and other various facilities required to accommodate that equipment). Also, the additional process steps imply additional process inputs including energy, chemistry and manpower, as well as an increased process risk associated with each finished cell. The ability to increase the efficiency of application of any and/or all of these inputs can have a multiplying effect on the overall product output produced by the manufacturing process.

The beneficial effects of the present invention, are not only evident in the improvements they afford to the basic process, but are multiplied by the various additional processes and process inputs associated with advanced process such as process 200.

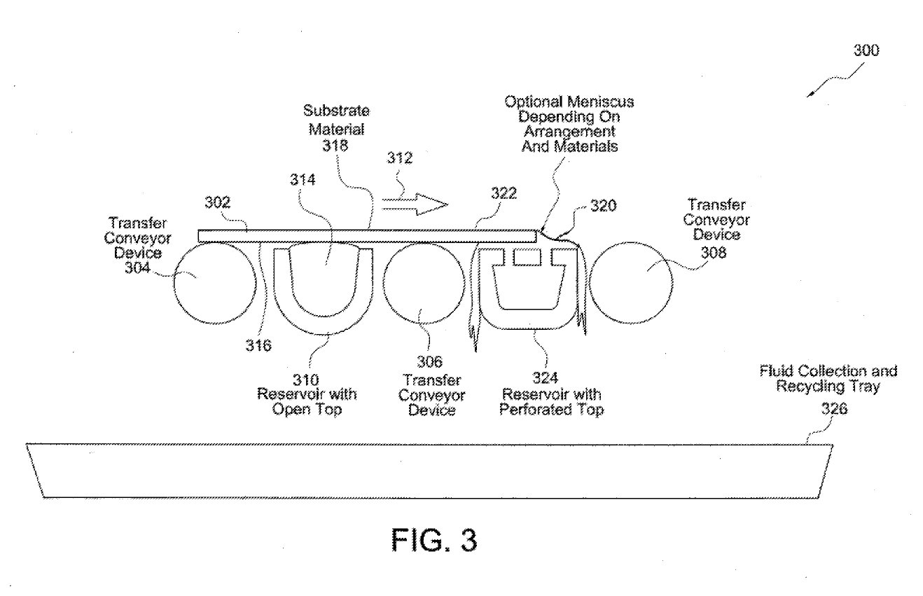

With the foregoing in mind, FIG. 3 shows one approach to single-sided processing 300 in the process of FIG. 3 according to principles of the present invention. Unlike previous bulk immersion and/or bulk-tank surface contact processes, the present invention includes a processing mode in which a substrate unit such as, for example, a semiconductor wafer 302 is supported on a plurality of transfer conveyor devices e.g., 304, 305, 308. In the illustrated embodiment, the transfer conveyor device is shown schematically as a rotatable support wheel. One of skill in the art will appreciate, however, that a variety of other transfer conveyor devices will be advantageously applied in corresponding embodiments of the invention according to the requirements of a particular process application.

As shown, a reservoir 310 is disposed, for example, between conveyor 304 and conveyor 306 such that as substrate 302 is transferred in direction 312 from conveyor 304 to conveyor 306 it passes above reservoir 310. In an exemplary application, a processing material 314, such as a fluid phase material, is provided within reservoir 310. An upper surface of the processing material 314 is arranged, by appropriate spatial juxtaposition with surfaces of the conveyor 304 and 306 to contact a lower surface 316 of the substrate 302 during its transfer from conveyor 304 to conveyor 306.

The resulting contact between processing material 304 and lower surface 316 results in a selective processing of lower surface 316 while leaving upper surface 318 of substrate 302 substantially unaffected.

Depending on the particular arrangement and materials involved, a processing system can be configured to optionally form a meniscus 320 effective to process edge surfaces 322 of the substrate 302, again without substantially affecting upper surface 318. In other applications of the invention, the system will be configured to avoid the formation of an edge meniscus 320 leaving edges 322 as well as upper surface 318 substantially un-affected by the processing material 314.

It will be appreciated by the practitioner of ordinary skill in the art, that the reservoir device 310 can be configured to include a variety of features including, for example, an open top as shown in reservoir 310, or a closed top having various perforations or other apertures as shown, for example, in reservoir 324. In either event, the reservoirs of system 300 are arranged such that a sump or other receptacle is available below the reservoirs to receive any processing material 326 that is displaced, and fails down from the surface of the reservoir.

Furthermore, it is an advantage of the present invention that reservoirs, in various configurations, can be co-mingled within a single processing station. In such arrangements, the characteristics of one reservoir will complement those of another reservoir to result in an overall improvement in process effectiveness.

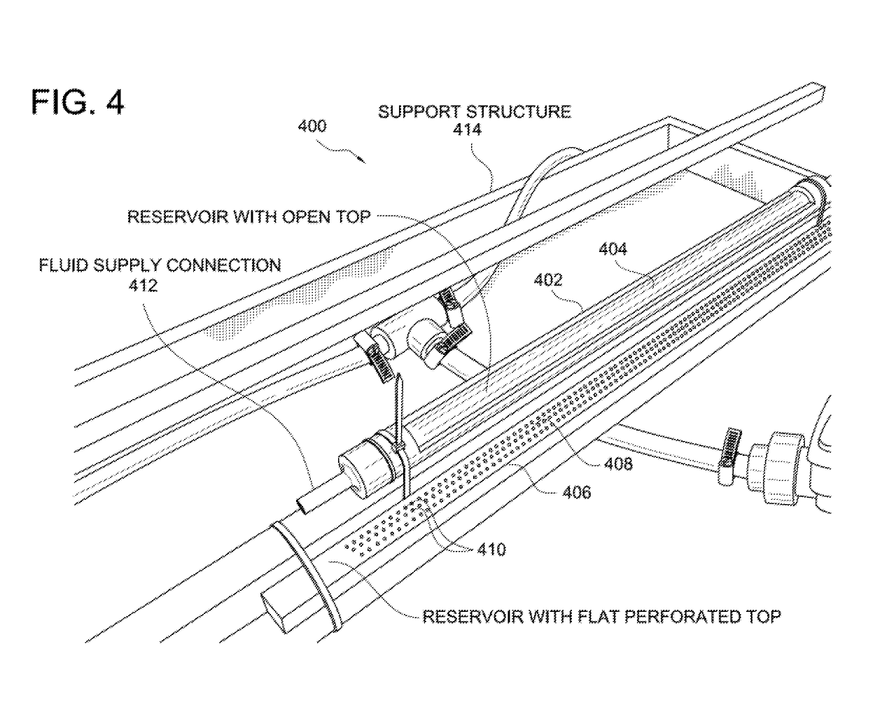

FIG. 4, in this context, shows an exemplary processing system 400 including a first exemplary reservoir 402 having an open top 404, and a second exemplary reservoir 406 with a substantially planar perforated top or upper surface 408. In the illustrated embodiment, the perforations 410 present in the top 408 of reservoir 406 are arranged in three generally linear rows substantially parallel to a longitudinal axis of the reservoir 406. As will be discussed below in additional detail, however, a variety of other patterns and arrangements of apertures are contemplated to be within the scope of the invention.

As illustrated, reservoir 402 includes a fluid supply connection 412 for receiving, for example, a continuous and/or controlled supply of processing material. Further, both reservoirs 402 and 406 are mutually supported within a support structure 414, which also supports various ancillary equipment including, without limitation and for example, conveyor apparatus, piping and manifold apparatus, sumps, control processors, pumps, sensors, safety and process-hygiene shielding, and any other equipment appropriate to the requirements of a particular process or application.

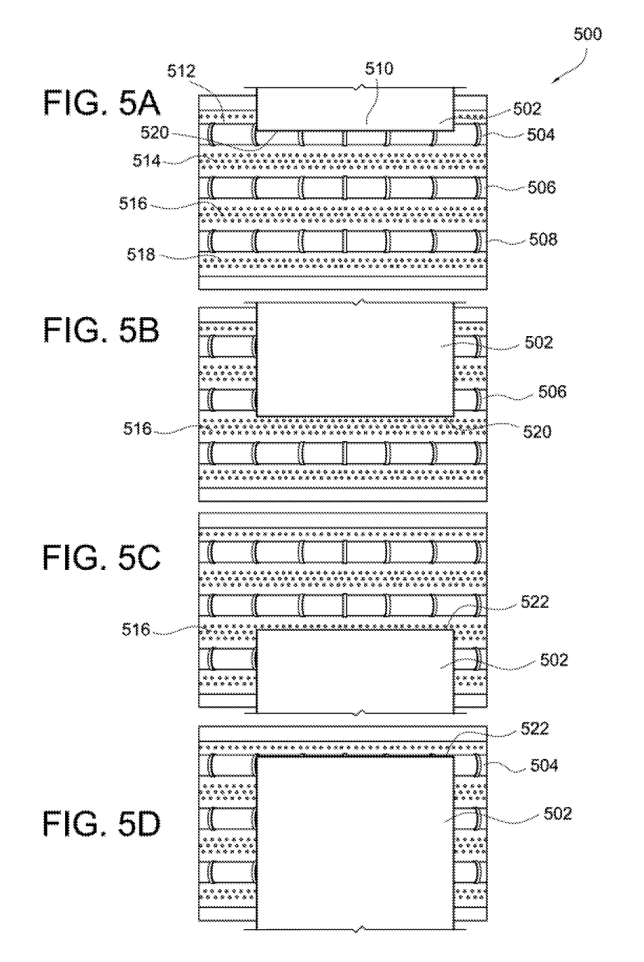

FIGS. 5A-5D show a chronological succession of images 500 illustrating the passage of an exemplary 502 substrate through a portion of an exemplary processing system according to principles of the invention. As evident in FIG. 5A the visible portion of the processing system 500 includes first 504, second 506 and third 508 transfer conveyor devices. Here the conveyor devices are illustrated as chemically inert shafts supporting respective pluralities of inert O-rings which would serve as tires to support a substrate 510. Again, it will be understood that other conveyor arrangements will be appropriate to respective applications of the invention.

Disposed between and adjacent to the transfer conveyor devices 504, 506 and 508, are respective reservoirs 512, 514, 516 and 518. Here the reservoirs are shown as having substantially planar perforated upper surfaces with three rows each of perforations generally aligned with respective longitudinal axes of the reservoir devices. Again, this arrangement of perforations is merely illustrative, and other arrangements including open top, longitudinally (counter direction of travel) slotted, transversely (direction of travel) slotted, diagonally slotted, helically slotted, randomized, and other arrangements are contemplated within the scope of the invention.

As noted, the chronological progress of the substrate 510 passed the reservoirs 512, 514, 516 and 518 in succession as illustrated by the figures. Thus, for example, in FIG. 5A a leading edge 520 of the substrate 510 is visible adjacent and generally parallel to conveyor 504. In FIG. 5B, leading edge 520 has passed conveyor 506 and is disposed adjacent to reservoir 516. In FIG. 5C leading edge 520 has just passed out of the image, and trailing edge 522 of the substrate 502 is visible adjacent conveyor 504. In FIG. 5D leading edge 520 has passed out of the image, and trailing edge 522 of the substrate 502 is visible adjacent reservoir 516.

In various embodiments of the invention, each of reservoirs 512, 514, 516, 518 may be arranged and configured to dispense a common processing material with common processing parameters such as, for example, pressure, volume, temperature, concentration, etc. In other embodiments of the invention, each of reservoirs 512, 514, 516 and 518 may be arranged to dispense a common processing material at different processing parameters, arranged to dispense different processing materials at common processing parameters, arranged to dispense different processing materials at different processing parameters and/or variable processing materials at discreetly and/or continuously varying processing parameters.

The ability to configure a system including a plurality of reservoirs to provide the same and/or different respective processing materials at a variety of constant or variable processing parameters vastly increases the flexibility and capability of a system prepared according to principles of the invention.

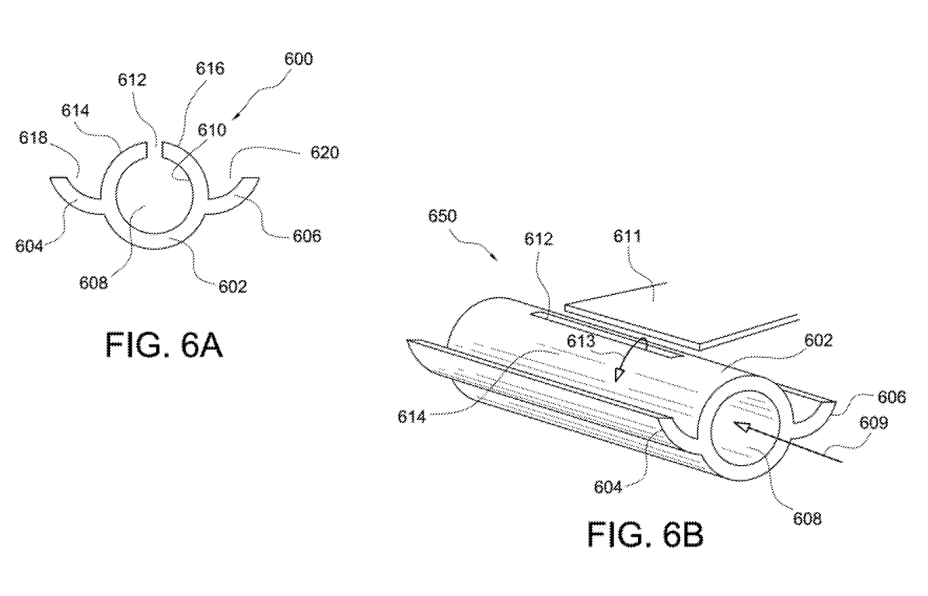

This flexibility is further augmented by the additional features of the invention described below. In particular, FIG. 6A shows, in cross-section, a further exemplary reservoir 600 prepared according to principles of the invention. The reservoir 600 of FIG. 6 includes a reservoir body portion 602 and first 604 and second 606 gutter portions. A longitudinal cavity 608 is defined within the reservoir portion 602 by internal surface regions 610 and one or more apertures 612. The one or more apertures 612 allow a processing fluid egress from within the internal longitudinal cavity 608 such that the processing fluid then flows over external surface regions 614, 616 and is received in channels 618, 620 formed by respective upper surfaces of the gutter portions 604, 606.

In certain embodiments, a pumping device and/or system will be provided to effect a continuous flow of processing fluid through the internal longitudinal cavity, and across the external surface regions 614, 616, where the processing fluid will come into contact with a lower surface of a work in process substrate.

Further clarifying this arrangement, FIG. 6B shows, in perspective view, a portion of a reservoir 650 having a cross-section like that of reservoir 600. Again, the reservoir includes a reservoir body portion 602 and first 604 and second 606 gutter portions. An exemplary aperture 612 allows a processing fluid pumped through longitudinal cavity 608 along direction 609 to exit the longitudinal cavity and contact a lower surface of a work in process substrate 611 as indicated by arrow 613. Excess processing fluid then proceeds to flow over the upper surfaces, e.g. 614 of the reservoir 602 until it is collected by the gutter 604 and 606. Thereafter, the excess processing fluid flows under the influence of gravity along the gutters and is returned to a collection tank.

It should be noted that reservoir 600 may be mounted in a support structure like that described and shown 414 in FIG. 4, and that support structure may include a common sump disposed above as plurality of reservoirs to collect any processing fluid that escapes the gutter portions 604, 606. Nevertheless, in certain applications, the gutter portions will be effective to collect a majority of overflowing processing fluid so that the same can be returned and recirculated.

It will be understood that, because the gutters are associated with a particular reservoir, several distinct chemistries (i.e. processing fluid) can be applied to a processing substrate within a single processing station (i.e., support structure). Thus, for example, a single station could include preparatory steps such as printing and pre-etching, principal processing steps such as etching, and post processing steps such as further rinsing. Moreover, by changing the fluids circulated through respective reservoirs, the process can be readily altered with a minimum of downtime and cost.

Further, as will be discussed below, reservoirs can be provided on a modular basis so that the reservoir and gutter system can be readily removed from a processing station and replaced with a different module. One of skill in the art will appreciate that modules can be prepared using different materials to meet different purposes. Consequently, modules of different chemical resistance can be exchanged in accordance with a corresponding change in desired process chemistry.

It should also be noted that, while the reservoir illustrated as 600 and 650 is shown with a substantially circular cross-section and a generally rectangular slot 612, any of a wide variety of geometric configurations can equally well be employed. Thus, a reservoir having a rectangular cross-section can be provided with gutters. Likewise an L-shaped reservoir can be provided and include an integrated gutter. Similarly, the top surface of a reservoir can be substantially flat or have any curve appropriate to the needs of a particular application. A variety of perforations and slots disposed in various orientations can be provided, again according to the needs of a particular processing application. Finally, it should be noted that, while the embodiments illustrated as 600 and 650 include integrated gutter portions, in other embodiments the reservoir portion and the gutter portion will be prepared as separate elements that can be combined according to particular needs and replaced independently where appropriate.

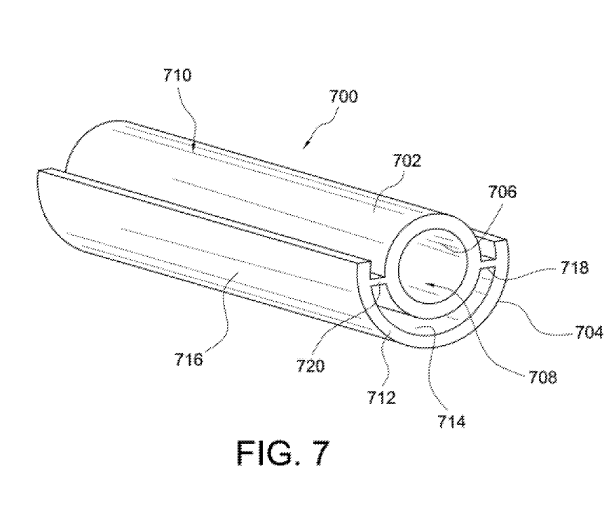

FIG. 7 shows a reservoir assembly 700 according to a further embodiment of the invention. The reservoir assembly includes a first reservoir portion 702 and a second gutter portion 704. The reservoir portion 702 includes an internal surface region 706 defining a longitudinal internal cavity 708. A plurality of perforations, slots or other apertures (not shown) are provided in an upper external surface region 710 of the reservoir portion to allow a processing fluid to flow from within the longitudinal cavity 708 out and over the external upper surface region 710.

Gutter portion 704 includes a longitudinal member 712 with an internal surface region 714 and an external surface region 716. One or more support spacers e.g., 718, 720 are shown disposed between internal surface region 714 and a corresponding external surface region 710 of reservoir portion 702. The support spacers 718, 720 serve to maintain the reservoir portion 702 and the gutter portion 704 in a substantially fixed spatial relationship with respect to one another.

In certain embodiments, the spacer support portions 718, 720 are substantially fixedly coupled to gutter portion 704 at corresponding portions of internal surface region 714. In other embodiments, the spacer support portions 718, 720 are substantially fixedly coupled to reservoir portion 702 at corresponding portions of external surface region 710. In still further embodiments the spacer support portions 718, 720 are substantially fixedly coupled to both the reservoir portion 702 and the gutter portion 704, and in still further embodiments, the spacer support portions 718, 720 are independent of and/or removably disposed between the reservoir portion 702 and the gutter portion 704. In certain embodiments, a plurality of spacers support portions e.g., 718, 720 are mutually coupled to one another, but independent of the corresponding reservoir portion 702 and gutter portion 704.

One of skill in the art will appreciate that FIG. 7 illustrates a manufacturing method according to one aspect of the invention. According to such a manufacturing method, a first generally rigid tube is provided. The first generally rigid tube is provided with a slot or other preparation at an upper surface region thereof by, for example, molding cutting or milling. A second generally rigid tube is also provided. The second rigid tube is divided approximately in half longitudinally by cutting, milling, slitting, or other processing and one half thereof is disposed below the first generally rigid tube such that the first tube is oriented with the preparation or other holes facing generally upward. One or more support spacers are provided and disposed between the second generally rigid tube and the first generally rigid tube. In certain embodiments, the one or more support spacers are substantially permanently coupled in place between the first generally rigid tube and a second generally rigid tube by any appropriate coupling method such as, for example, ultrasonic welding, plastic thermal welding, adhesive bonding, or fastener coupling using, for example, screws, staples, nails, rivets, brads, etc.

It will be appreciated by one of skill in the art, that the manufacturing method described, above will readily be applied to the wide variety of cross-sections including, for example, circular cross-section, triangular cross-section, square cross-section, rectangular cross-section, pentagonal cross-section, hexagonal cross-section, heptagonal cross-section, octagonal cross-section, etc. Likewise, whereas in some embodiments, the general geometry of the cross-section of the reservoir portion will be similar to that of the gutter portion, in other embodiments of the invention, the cross-sectional geometry of the reservoir portion will differ from that of the glitter portion. Thus, for example and without limitation, a reservoir portion having a circular cross-section will be combined in certain embodiments with a gutter portion having a square cross-section.

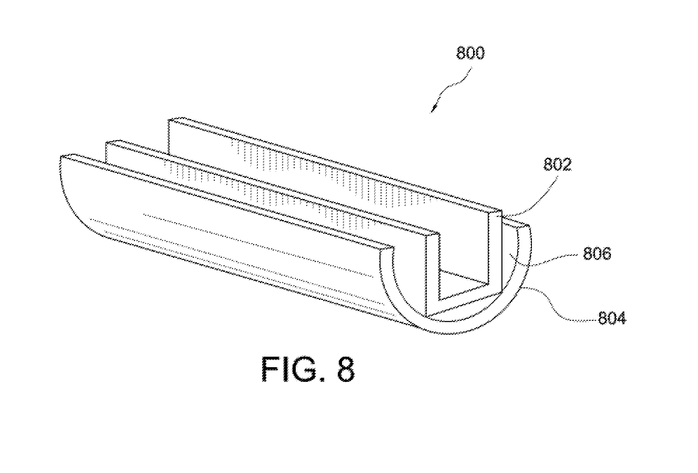

One such exemplary combination is shown in schematic perspective view in FIG. 8. FIG. 8 shows a portion of a reservoir apparatus 800 including a reservoir portion 802 having a generally square cross-section and an open top and a gutter portion 804 having a generally semicircular cross-section. Both the reservoir portion 802 and the gutter portion 804 are prepared, in certain embodiments, by removing the upper portion from respective closed longitudinal tubes of corresponding cross-section. It will be noted that in certain embodiments of the invention according to this configuration, no support spacer is required. Rather, the reservoir portion 802 may be arranged to be bonded to or simply rest upon an internal surface region 806 of gutter portion 804.

In a further aspect according to principles of the invention, a module can be prepared including a reservoir portion and a gutter portion along with a variety of ancillary equipment. Thus, for example, a module may include a variety of process maintenance and sensing equipment.

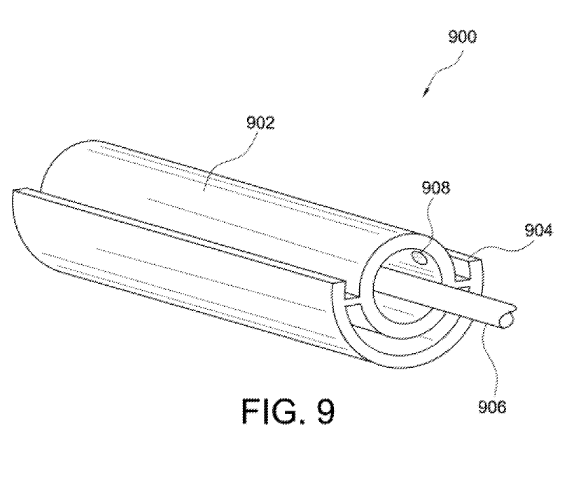

FIG. 9 shows one such exemplary module 900 including a reservoir portion 902 and gutter portion 904 and a coaxial temperature control portion 906. The coaxial temperature control portion 906 will, in certain embodiments, be implemented as a polytetrafluoroethylene (PTFE—Teflon®) coated resistive electric heating element. In other embodiments, temperature control portion 906 will include a tube including any appropriate material such as, for example, PTFE, polyvinyl chloride (PVC), polyethylene (PE), ultrahigh molecular weight polyethylene (UHMWPE), polypropylene (PP), polyvinylidene difluoride (PVDF—Kynar®), polyamide (nylon®), polyaramid (Kevlar®), stainless steel, titanium, or any other appropriate material according to the thermal and chemical requirements of a particular application. The tube of the temperature control portion 906 will be arranged to receive a thermal working fluid (e.g., in liquid and/or gaseous form) flowing therethrough for purposes of heating or cooling the processing fluid flowing within the internal longitudinal cavity of the reservoir 902. In other embodiments, a heating or cooling element will, alternatively or in addition, be provided in the gutter portion 904 to, for example, counteract the effects of an exothermic or endothermic reaction between the processing fluid and the substrate.

In like fashion, one or more sensor devices 908 may be disposed within or external to the reservoir 902 for sensing temperature, chemical composition, flow rates, and any other appropriate process variable related to the processing fluid. In certain embodiments, such sensor devices will communicate wirelessly with a transceiver device. In other embodiments, a signal conveying device such as, for example, an electrical wire or optical fiber will be provided to signalingly couple the sensor devices to an external control system.

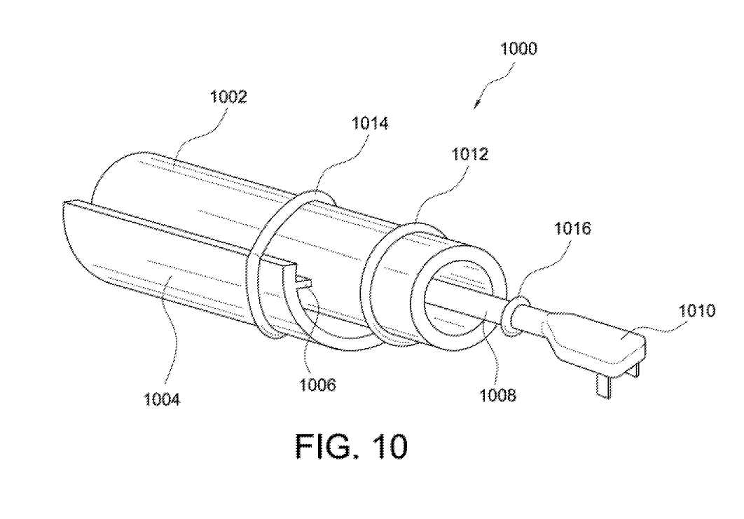

It will also be appreciated that, as further described below, a device according to the invention, and corresponding inventive manufacturing method, may include the application of certain terminal features to the ends and/or to intermediate regions of the reservoir and gutter portions so that the reservoir portion and gutter portion may be readily removed and reinstalled in a supporting structure for service, reconfiguration, or other purposes. Likewise, coupling features may be provided for cooling and instrumentation devices such that the entirety of the reservoir portion, the gutter portion, and any ancillary equipment forms a removable module. Thus, with reference to FIG. 10 one sees a removable module 1000 including a reservoir portion 1002, a gutter portion 1004, a spacer device 1006 and a heater element 1008. As illustrated, the heater element 1008 includes an electrical coupling device 1010, here shown as an electrical plug. Each of the reservoir portion 1002, gutter portion 1004 and heater element 1008 includes a respective groove supporting a respective O-ring 1012, 1014, 1016. The O-rings 1012, 1014 and 1016 provide rapid and effective seals to prevent unwanted ingress and egress of fluid. It will be appreciated that while module 1000 employs O-ring seals, a wide variety of other geometric configurations of seals will also be beneficially employed in corresponding embodiments of the invention.

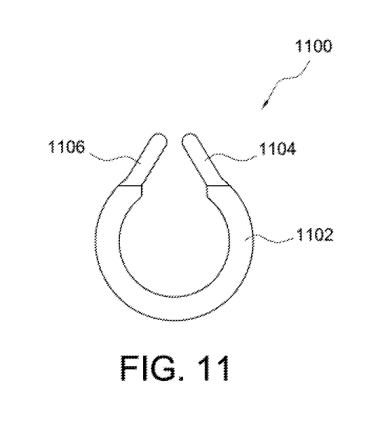

Likewise, flexible material will also be employed in certain embodiments of the invention adjacent to the apertures that allow fluid to exit the reservoir portion and impinge on the respective lower surfaces of the substrates. Thus, FIG. 11 shows, in cross-section, a portion of a reservoir 1100 having a generally rigid lower portion 1102 and a generally flexible upper portion 1104, 1106. In certain embodiments, the generally rigid lower portion 1102 will be formed of a substantially rigid polymeric material such as, for example, PVC. The generally flexible upper portion will be formed of, for example, an elastomeric material such as, for example, polyurethane. Naturally, other materials will be selected and applied where appropriate according to the process requirements of a particular application.

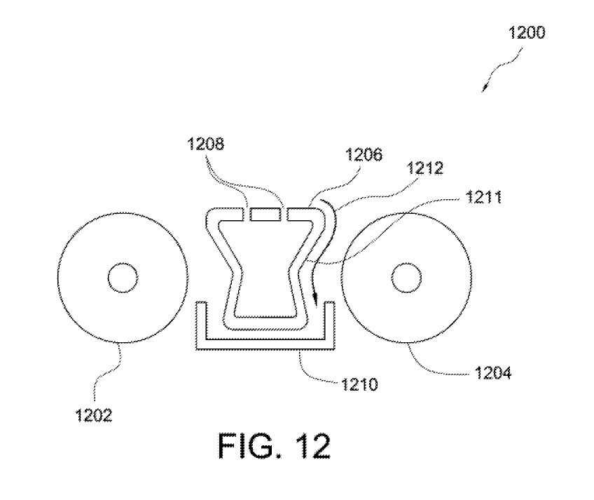

Further, it should be noted that while most of the illustrated reservoirs and gutter devices shown above are generally convex in cross-section, other applications and embodiments of the invention will employ reservoirs and gutter devices of that have concave surface regions. Having concave surface regions will be particularly advantageous in that they will allow the reservoir module to be placed in close proximity to an adjacent conveyor device. Moreover, in certain embodiments, materials will be employed having desirable wetting characteristics such that any overflow processing fluid will tend to follow such a concave surface region around an external surface of a reservoir portion and into a gutter portion. FIG. 12 illustrates, in cross-section, one such arrangement 1200 including a first 1202 and second 1204 conveyor device disposed adjacent to a reservoir portion 1206 having a plurality of apertures 1208 and a gutter portion 1210. In such an embodiment, the shape and materials of the reservoir portion would be chosen to ensure that overflow processing fluid would follow the concave external surface region 1211 of the reservoir portion down along arrow 1212 and into gutter portion 1210.

It should also be noted that appropriately shaped and configured modules allow for the introduction of additional conveyor devices between modules to provide for superior stabilization of substrates before, during and after processing.

As noted above, certain modules will include process fluid inputs at one or both longitudinal ends of the reservoir portion. In still other embodiments, additional inputs will be provided into the reservoir portion at intermediate points along its length. These additional inputs will be supplied by corresponding manifold piping. In certain embodiments, one process fluid input will be provided for each lane of semiconductor substrates within a processing system. In other embodiments, a single slot will traverse each lane of a processing system to ensure uniform processing across the entire width of the corresponding substrate.

Also, to maintain consistent pressure and flow along the length of the reservoir, the configuration of slots may vary in surface area. For example, a slot may diverge (i.e., become wider) towards the center of a reservoir and narrower towards its end. In certain embodiments, the size of an egress aperture will be adjustable. In other embodiments, the edges of an aperture will include certain features including triangular features, crenellated features, or other features effective to provide improved, laminar flow and/or turbulent flow according to the requirements of a particular application.

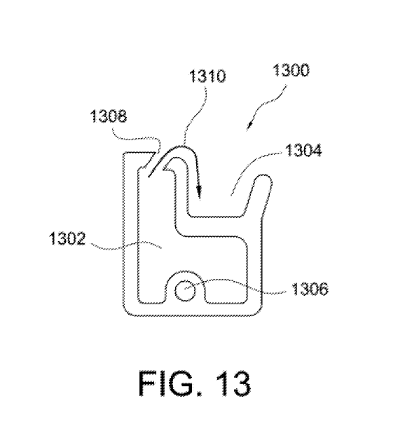

In a still further embodiment of the invention 1300 as illustrated in FIG. 13, a single integrated extrusion includes a reservoir portion 1302, a gutter portion 1304 and a heating portion 1306. In certain embodiments of the invention, a post-extrusion manufacturing step will include the cutting of a reservoir aperture 1308 into an appropriate portion of the reservoir to allow a processing fluid to flow outwardly following arrow 1310 and into the gutter portion 1304.

It will be appreciated that, in certain embodiments, the invention will include manufacturing methods for the production of special extrusions of polymer, reinforced polymer, aluminum alloy or any other material appropriate to provide the particular geometric arrangement required. In addition, a variety of materials will be employed beneficially including, and without limitation, suitable polymers including polyethylene, polypropylene, polybutylene, polystyrene, polyester, acrylic polymers, polyvinylchloride, polyamide, or polyetherimide like ULTEM®; a polymeric alloy such as Xenoy® resin, which is a composite of polycarbonate and polybutyleneterephthalate or Lexan® plastic, which is a copolymer of polycarbonate and isophthalate terephthalate resorcinol resin (all available from GE Plastics), liquid crystal polymers, such as an aromatic polyester or an aromatic polyester amide containing, as a constituent, at least one compound selected from the group consisting of an aromatic hydroxycarboxylic acid (such as hydroxybenzoate (rigid monomer), hydroxynaphthoate (flexible monomer), an aromatic hydroxyamine and an aromatic diamine, (exemplified in U.S. Pat. Nos. 6,242,063, 6,274,242, 6,643,552 and 6,797,198, the contents of which are incorporated herein by reference), polyesterimide anhydrides with terminal anhydride group or lateral anhydrides exemplified in U.S. Pat. No. 6,730,377, the content of which is incorporated herein by reference) or combinations thereof.

In addition, any polymeric composite such as engineering prepregs or composites, which are polymers filled with pigments, carbon particles, silica, glass fibers, conductive particles such as metal particles or conductive polymers, or mixtures thereof may also be used. For example, a blend of polycarbonate and ABS (Acrylonitrile Butadiene Styrene) may be used.

Elastomers that may be used in various embodiments of the invention include various copolymers or block copolymers (Kraton®) available from Kraton Polymers such as styrene-butadiene rubber or styrene-isoprene rubber, EPDM (ethylene propylene diene monomer) rubber, nitrite (acrylonitrile butadiene) rubber, polyurethane, polybutadiene, polyisobutylene, neoprene, natural latex rubber and the like. Foam materials may be closed cell foams or open cell foams, and may include, but is not limited to, a polyolefin foam such as a polyethylene foam, a polypropylene foam, and a polybutylene foam; a polystyrene foam; a polyurethane foam; any elastomeric foam made from any elastomeric or rubber material mentioned above; or any biodegradable or biocompostable polyesters such as a polylactic acid resin (comprising L-lactic acid and D-lactic acid) and polyglycolic acid (PGA); polyhydroxyvalerate/hydroxybutyrate resin (PHBV) (copolymer of 3-hydroxy butyric acid and 3-hydroxy pentanoic acid (3-hydroxy valeric acid) and polyhydroxyalkanoate (PHA) copolymers; and polyester/urethane resin. One of skill in the art will appreciate that the foregoing are merely exemplary of a wide variety of possibilities that would be applied in appropriate applications.

Suitable metal or metallic alloys for use in preparing modules according to principles of the invention may include stainless steel; aluminum; an alloy such as Ni/Ti alloy; any amorphous metals including those available from Liquid Metal, Inc. or similar ones, such as those described in U.S. Pat. No. 6,632,611, and U.S. Patent Application No. 2004/0121283, the entire contents of which are incorporated herein by reference.

One of skill in the art will appreciate that the benefits of the modular arrangements proposed above include the possibility of rapidly reconfiguring portions of a manufacturing process to include additional process steps, fewer process steps, and/or alternative process steps. Active process steps can be readily interspersed with rinsing process steps, surfactant process steps, and drying process steps. Acidic and alkaline process steps can be readily alternated while, notwithstanding dose proximity of the modules, the corresponding chemistries are kept separate. Binary and/or multipart chemistries can be effected where the first module applies a basic chemistry and a second module applies a catalyst or other activating component such that the chemistry becomes active only with the second application.

In addition, a support structure can be provided including separate ventilation facilities associated with each module receptacle or slot. This, again, allows the separation of disparate incompatible chemistries, notwithstanding close spatial proximity. Of course the application of such modules allow for a significant overall reduction in process line size. Moreover, like the reservoir modules, the ventilation modules may be removable and replaceable according to the requirements of a particular chemistry. Indeed, in certain embodiments of the invention, a chemistry module and ventilation module may be provided together as a kit or integrated unit for insertion into a support structure. In certain embodiments a business method will include the exchange of a previously employed module for a new module on a sale, rental or lease basis.

In certain embodiments, an upper surface of the reservoir portion will be replaceable without replacing the balance of the reservoir portion. In certain embodiments, the replaceable upper surface will include a particular desirable pattern provided on a stock or specialty basis. Any of a wide variety of patterns will be available including, for example, a plurality of circular holes, a plurality of polygonal holes, a plurality of longitudinal slots, a plurality of transverse slots, a plurality of slots disposed obliquely with respect to work in process direction of travel. Converging and/or diverging slots and holes will be provided where appropriate to a particular application. Of course, a particular reservoir module or reservoir surface will include any combination of the foregoing according to the requirements of a particular application.

Moreover, because of the proximity between perforations at the top of the reservoir portion and the associated gutter portion, exposure of the flowing chemistry to the ambient atmosphere is reduced, providing for reduced evaporation, contamination and/or oxidation of process chemicals. Furthermore, the overall small system volume requires less chemistry to be present within the machine or system at a particular time, reducing chemical inventory costs and minimizing environmental hazards and compliance costs. Likewise, in situ heating immediately prior to application of the process chemistry to a substrate tends to reduce input energy costs and evaporative losses.

In certain embodiments, the invention will include the foregoing described modules in conjunction with a wafer handling device system and method as described in international published application number WO2010/132098 the disclosure of which is herewith incorporated by reference in its entirety.

In certain further embodiments, the invention will include the foregoing described modules in conjunction with a wafer guide as described in international published application number WO2010/059205 the disclosure of which is herewith incorporated by reference in its entirety.

While the exemplary embodiments described above have been chosen primarily from the field of semiconductor processing, one of skill in the art will appreciate that the principles of the invention are equally well applied, and that the benefits of the present invention are equally well realized in a wide variety of other chemical processing systems including, for example, metal finishing systems and polymer coating systems. Further, while the invention has been described in detail in connection with the presently preferred embodiments, it should be readily understood that the invention is not limited to such disclosed embodiments. Rather, the invention can be modified to incorporate any number of variations, alterations, substitutions, or equivalent arrangements not heretofore described, but which are commensurate with the spirit and scope of the invention. Accordingly, the invention is not to be seen as limited by the foregoing description, but is only limited by the scope of the appended claims.

1. A chemical processing device comprising:
a reservoir having a first edge and a second edge;
a first conveyor device disposed adjacent to said first edge;
a second conveyor device disposed adjacent to said second edge such that said first and second edges are disposed between said first and second conveyor devices, said second conveyor device being adapted to receive and support a substrate material from said first conveyor device, whereby one surface of said substrate material contacts a fluid material disposed within said reservoir during a transition from said first conveyor device to said second conveyor device while a further surface of said substrate material remains substantially un-contacted by said fluid material.

2. A chemical processing device as defined in claim 1 wherein said reservoir includes a fluid supply connection for receiving a quantity of said fluid material into said reservoir and wherein at least one of said first and second edges is structured to allow a portion of said quantity of fluid material to flow away from said reservoir.

3. A chemical processing device as defined in claim 1 wherein at least one of said first and second edges comprises a junction, between a first surface region of said reservoir and a second surface region of said reservoir, said first surface region of said reservoir being disposed in a generally horizontal orientation said second surface region of said reservoir being disposed in a generally vertical orientation.

4. A chemical processing device as defined in claim 3 wherein said first surface region of said reservoir comprises a generally planar surface region.

5. A chemical processing device as defined in claim 3 wherein said first surface region of said reservoir comprises a curved surface region.

6. A chemical processing device as defined in claim 1 wherein said reservoir portion includes an external surface region, said external surface region incorporating an aperture, said aperture being structured and arranged to allow said fluid material to flow outwardly from an internal cavity within said reservoir and past said external surface region towards at least one of said first and second edges.

7. A chemical processing device as defined in claim 6 wherein said aperture is defined by a substantially circular edge.

8. A chemical processing device as defined in claim 6 wherein said aperture comprises a slot having a slot longitudinal axis.

9. A chemical processing device as defined in claim 6 wherein said slot longitudinal axis is disposed generally parallel to a longitudinal axis of said reservoir.

10. A chemical processing device as defined in claim 6 wherein said longitudinal axis is disposed generally perpendicular to a longitudinal axis of said reservoir.

11. A chemical processing device as defined in claim 6 wherein said longitudinal axis is disposed at an oblique angle with respect to a longitudinal axis of said reservoir.

12. A chemical processing system comprising:
a reservoir having a reservoir longitudinal axis;
a first conveyor device; and
a second conveyor device, said first and second conveyor devices being disposed adjacent to, and on respective opposite sides of, said reservoir, and arranged such that, during operation, a work in process element can pass from said first conveyor device across said reservoir to said second conveyor device, whereby a lower surface region of said work in process element comes into contact with a fluid material supported by said reservoir while leaving an upper surface of said work in process element substantially out of contact of said fluid material.

13. A chemical processing system as defined in claim 12 wherein said reservoir longitudinal axis is disposed generally perpendicular to a direction of motion of said work in process element.

14. A chemical processing system as defined in claim 12 wherein said reservoir comprises an upper surface region, said upper surface region including an aperture.

15. A chemical processing system as defined in claim 14 wherein said aperture comprises a generally polygonal hole.

16. A chemical processing system as defined in claim 14 wherein said aperture comprises a generally circular hole.

17. A chemical processing system as defined in claim 12, further comprising:
a further plurality of reservoirs, each of said reservoir and said further plurality of reservoirs including a respective integrated recapture gutter, each of said reservoir and said further plurality of reservoirs being removably supported by a common support structure to form together a processing module, such that any one of said reservoir and said further plurality of reservoirs may be independently replaced for service, and wherein each of said reservoir and said further plurality of reservoirs is coupled to a respective fluid source.

18. A chemical processing system as defined in claim 17 wherein one said respective fluid source is a rinse water fluid source and another said respective fluid source is a process chemical fluid source.

19. A chemical processing system as defined in claim 14 wherein said reservoir comprises a recapture gutter, said recapture gutter structured and arranged to receive a portion of said fluid material after said fluid material flows through said aperture.

20. A chemical processing system as defined in claim 19 wherein said recapture gutter is integrally formed with said reservoir.

21. A chemical processing system comprising:
a plurality of reservoirs, each reservoir of said plurality of reservoirs having a respective reservoir longitudinal axes;
a first conveyor device; and
a second conveyor device, said first and second conveyor devices being disposed adjacent to, and on respective opposite sides of one reservoir of said plurality of reservoirs, and arranged such that, during operation, a work in process element can pass from said first conveyor device across said one reservoir's longitudinal axis to said second conveyor device, whereby a lower surface region of said work in process element comes into contact with a first fluid material supported by said one reservoir while leaving an upper surface of said work in process element substantially out of contact of said first fluid material and wherein said one reservoir includes a recapture gutter, said recapture gutter structured and arranged to receive a portion of said first fluid material after said first fluid material flows through an aperture of said one reservoir, and wherein said one reservoir and the other reservoirs of said plurality of reservoirs are rapidly reconfigurable and arranged to receive alternative fluid materials.
